(19) United States
(12) Patent Application Publication
(10) Pub. No.: US 2014/0034948 A1
(43) Pub. Date: Feb. 6, 2014

(54) LED epitaxial Structure

(71) Applicants: Yang-Kuo Kuo, Longtan Township (TW); Chia-Yi Hsiang, Longtan Township (TW); Hung-Tai Ku, Longtan Township (TW)

(72) Inventors: Yang-Kuo Kuo, Longtan Township (TW); Chia-Yi Hsiang, Longtan Township (TW); Hung-Tai Ku, Longtan Township (TW)

(73) Assignee: Chung Shan Institute of Science and Technology, Armaments Bureau, M.N.D.

(21) Appl. No.: 13/612,779

(22) Filed: Sep. 12, 2012

(30) Foreign Application Priority Data
Aug. 3, 2012 (TW) 101127972

(51) Int. Cl. H01L 33/16

(52) U.S. Cl. 257/49; 257/E33.003

(57) ABSTRACT

An LED epitaxial structure includes the first layer thin film and the second layer thin film. The first layer thin film and the second layer thin film are polycrystalline aluminum nitride and single crystal aluminum nitride respectively, which have good thermal conductivity, insulation, mechanical intensity, and chemistry stability. Based on the substrate mentioned above, growing a single crystal gallium nitride on the second layer thin film as the third layer thin film allows the single crystal aluminum nitride and gallium nitride to have good lattice and thermal expansion match, resulting in the promotion of light emitting and thermal conduction efficiency.

### BACKGROUND OF THE INVENTION

1. Field of the invention

The present invention relates to an LED epitaxial structure, in particular, to a substrate material used for the epitaxial structure in the LED manufacturing process.

2. Description of Related Art

Regarding the LED light emitting device structure, substrate selection has a considerable influence on the characteristics and performance of the epitaxial wafer, such as: brightness, luminous efficiency and component lifespan, which are due to the lattice and thermal expansion differences between substrate and epitaxial materials. (due to differences between TE, problems arise)

The substrate materials currently used in the general blue LED are sapphire (Al2O3) and silicon carbide (SiC).

Comparatively speaking, Sapphire substrate has a lower cost, but poor cooling capacity (about 40 W/mK), which needs flip-chip process or other special process to improve the cooling capacity, resulting in the increment of costs.

Moreover, the lattice and thermal expansion match of the sapphire and gallium nitride (GaN) are poor, and the lattice constant between the c-cut sapphire and gallium nitride is about 15% to 30% mismatch, leading to the decrease of epitaxial quality of the gallium nitride.

SiC has better thermal conductivity (about 160 W/mK), the lattice constant between the SiC and the gallium nitride is about 3.5% mismatch, which is better than the sapphire. However, since the cost of SiC substrate is high, the general LED epitaxial plants still use sapphire as the substrate for epitaxial growth.

Therefore, how to overcome the above mentioned shortcoming is the issue the industry needs to resolve.

### SUMMARY OF THE INVENTION

The objective of the present invention is to provide an LED epitaxial structure, which allows the semiconductor material to grow on an epitaxial substrate, so as to form as a semiconductor composite structure.

In order to achieve the above mentioned objective, a material of Aluminum Nitride (AlN) with wide band gap as well as high thermal conductivity is used. First of all, preparing the first layer thin film of a polycrystalline aluminum nitride, the second layer thin film of a single crystal aluminum nitride is epitaxially grown on the first layer thin film of the polycrystalline aluminum nitride via an epitaxial process, so as to form the epitaxial substrate.

In addition, the third layer thin film of a single crystal gallium nitride is epitaxially grown on the second layer thin film of the single crystal aluminum nitride via another epitaxial process, operating as a light emitting layer. Because both the thermal expansion coefficients and the lattice constants of the aluminum nitride materials and the gallium nitride materials are quite close to each other, which allows the second layer thin film of the single crystal aluminum nitride and the third layer thin film of a single crystal gallium nitride to have a good lattice match and allow the heat dissipation, lifespan and light emitting efficiency of the LED to achieve good improvements.

### BRIEF DESCRIPTION OF THE DRAWINGS

The invention, as well as its many advantages, may be further understood by the following detailed description and drawings in which:

FIG. 1 is a schematic diagram showing the substrate of the LED epitaxial structure of the present invention; and

FIG. 2 is an LED epitaxial structure of a preferred embodiment of the present invention.

### DETAILED DESCRIPTION OF THE INVENTION

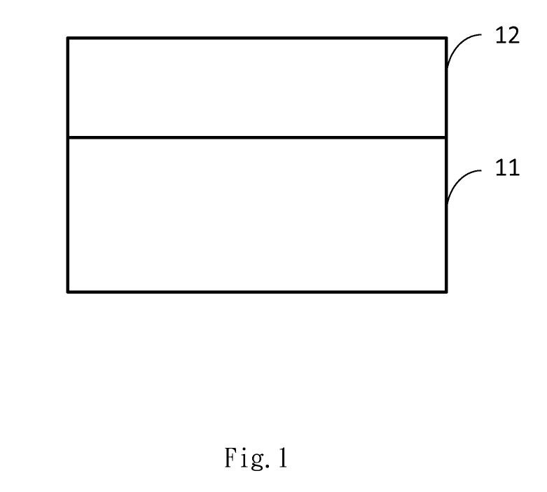

With reference to FIG. 1, the LED epitaxial structure provided by the embodiment of the present invention is an epitaxial substrate, which is composed of a first layer thin film 11 and a second layer thin film 12.

First of all, the first layer thin film 11 is used as a substrate and an epitaxial process is processed on one side of the first layer thin film 11. An organometallic compound is converted into the second layer thin film 12 on the side of the first layer thin film 11 via chemical reactions in the epitaxial process of metal organic chemical vapor deposition (MOCVD).

The first layer thin film 11 is a polycrystalline aluminum nitride thin film; the second layer thin film 12 is a single crystal aluminum nitride thin film.

Because the aluminum nitride has the advantages of wide energy band gap (6.2 eV), high thermal conductivity (320 W/mK), good electrical insulation, high mechanical strength and chemical stability, and there are good lattice and thermal expansion between the polycrystalline aluminum nitride thin film and the single crystal aluminum nitride thin film, the single crystal aluminum nitride thin film can be epitaxially grown on the polycrystalline aluminum nitride thin film, so as to acquire the epitaxial substrate with better lattice quality.

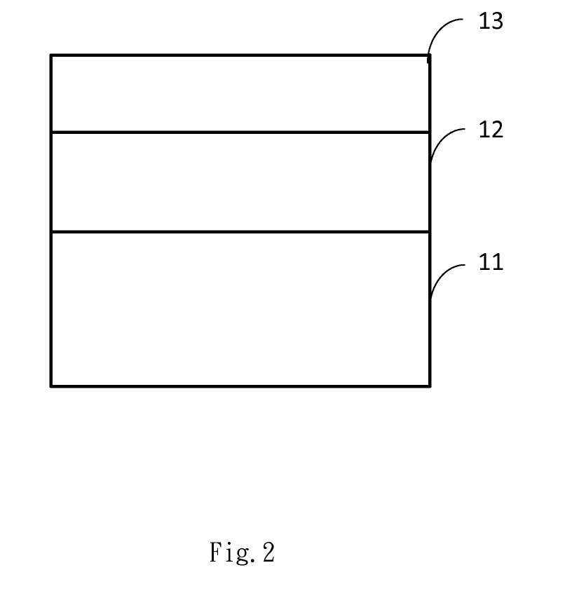

Furthermore, with reference to FIG. 2, the epitaxial substrate is proceeded with another epitaxial process via metal organic chemical vapor deposition, so that the second layer thin film 12 of the epitaxial substrate grows into a third layer thin film 13, which provides light emitting materials for a single crystal gallium nitride thin film.

Since the thermal expansion coefficients and the lattice constants of both the aluminum nitride and gallium nitride epitaxial layer material are very close to each other, the lattice of both the single crystal gallium nitride thin film and the single crystal aluminum nitride thin film is good and thermal expansion between them is small, which allows the single crystal gallium nitride thin film to reduce generation of the dislocation density in the lattice during the epitaxial process; and the polycrystalline aluminum nitride thin film and the single crystal aluminum nitride thin film to have good thermal conductivity, which avoids hot skew caused by thermal expansion mismatch in high temperature, therefore using the aluminum nitride as a high power LED epitaxial substrate has a considerable potential for development.

It is clear from the above description, the LED epitaxial structure provided by the present invention is the epitaxial substrate composed of the first layer thin film 11 and the second layer thin film 12, which is epitaxially grown as the second layer thin film 12 on one side of the first layer thin film 11 via metal organic chemical vapor deposition, wherein the first layer thin film 11 and the second layer thin film 12 are the polycrystalline aluminum nitride thin film and the single crystal aluminum nitride thin film respectively.

Further, the second layer thin film 12 is epitaxially grown as the third layer thin film 13, which is the single crystal gallium nitride thin film, and the single crystal gallium nitride and the single crystal aluminum nitride have a good lattice and thermal expansion match, therefore achieves the goal of promoting the light emitting efficiency and extending the lifespan of the LED.

Many changes and modifications in the above described embodiment of the invention can, of course, be carried out without departing from the scope thereof Accordingly, to promote the progress in science and the useful arts, the invention is disclosed and is intended to be limited only by the scope of the appended claims.

1. An LED epitaxial structure comprising:
a substrate, comprising:
a polycrystalline aluminum nitride thin film; and
a single crystal aluminum nitride thin film epitaxially growing on one side of the polycrystalline aluminum nitride thin film; and
a single crystal gallium nitride layer directly contacting and epitaxially growing on the single crystal aluminum nitride thin film.

2. (canceled)

3. (canceled)

4. The epitaxial structure as claimed in claim 1, wherein the polycrystalline aluminum nitride thin film and the single crystal aluminum nitride thin film are both made of by aluminum nitride.

5. The epitaxial structure as claimed in claim 4, wherein the aluminum nitride material has an energy band gap of 6.2 eV and a thermal conductivity of 320 W/mK.
